(19) United States
(12) Patent Application Publication
(10) Pub. No.: US 2024/0387486 A1
(43) Pub. Date: Nov. 21, 2024

(54) SEMICONDUCTOR PACKAGE

(71) Applicant: SAMSUNG ELECTRONICS CO., LTD., Suwon-si (KR)

(72) Inventors: Dahee Kim, Suwon-si (KR); Hongwon Kim, Suwon-si (KR); Jae-Ean Lee, Suwon-si (KR); Taehoon Lee, Suwon-si (KR); Gyujin Choi, Suwon-si (KR)

(21) Appl. No.: 18/584,905

(22) Filed: Feb. 22, 2024

(30) Foreign Application Priority Data
May 19, 2023 (KR) 10-2023-0064828

(51) Int. Cl. H01L 25/16; H01L 23/00; H01L 23/31; H01L 23/48; H01L 23/498

(52) U.S. Cl. CPC H01L 25/16; H01L 23/3107; H01L 23/481; H01L 23/49811; H01L 23/49822; H01L 24/16; H01L 28/60; H01L 2224/16145; H01L 2224/16227; H01L 2224/16238; H01L 2924/19041

(57) ABSTRACT

An example semiconductor package includes a substrate, a first semiconductor chip mounted on the substrate, a mold layer on the substrate to cover the first semiconductor chip, and outer terminals positioned below the substrate. The substrate includes a first interconnection layer, a second interconnection layer on the first interconnection layer, a passive device mounted on a bottom surface of the second interconnection layer, and a connection member at a side of the passive device and between the first interconnection layer and the second interconnection layer to connect the first interconnection layer to the second interconnection layer. The outer terminals are coupled to a bottom surface of the first interconnection layer, the passive device includes a first pad on a top surface of the passive device, and an interconnection pattern of the second interconnection layer contacts the first pad.

### CROSS-REFERENCE TO RELATED APPLICATION

This application claims priority under 35 U.S.C. § 119 to Korean Patent Application No. 10-2023-0064828, filed on May 19, 2023, in the Korean Intellectual Property Office, the entire contents of which are hereby incorporated by reference.

### BACKGROUND

In light of recent advancements in the electronics industry, the demand for high-performance, high-speed, and compact electronic components has been steadily increasing. As a result, there is a development of packaging technologies that allow for the mounting of multiple semiconductor chips within a single package.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With the recent development of the electronics industry, a semiconductor package technology is developing in various ways with the goal of miniaturization, weight reduction, and manufacturing cost reduction. Furthermore, as the utilization of this technology expands to different fields, including mass storage devices, several types of semiconductor packages are emerging.

As an integration density of a semiconductor chip increases, a size of a semiconductor chip is gradually decreasing. However, in the case where the size of the semiconductor chip is reduced, it is increasingly difficult to attach many solder balls to the semiconductor chip and to handle and test the solder balls. In addition, it is necessary to diversify a board in accordance with a size of a semiconductor chip, and this is another difficult problem. To solve these problems, a fan-out panel level package has been proposed. In the fan-out semiconductor package, the area of a redistribution structure may be larger than the area of the semiconductor chip. In this case, the semiconductor package may require an excessively large area compared to the effectiveness of the semiconductor chip.

### SUMMARY

The present disclosure relates to compact semiconductor packages, as well as semiconductor packages with improved electrical characteristics.

In some implementations, a semiconductor package includes a substrate, a first semiconductor chip mounted on the substrate, a mold layer provided on the substrate to cover the first semiconductor chip, and outer terminals provided below the substrate. The substrate includes a first interconnection layer, a second interconnection layer on the first interconnection layer, a passive device mounted on a bottom surface of the second interconnection layer, and a connection member provided at a side of the passive device and between the first interconnection layer and the second interconnection layer to connect the first interconnection layer to the second interconnection layer. The outer terminals are coupled to a bottom surface of the first interconnection layer, the passive device includes a first pad provided on a top surface thereof, and an interconnection pattern of the second interconnection layer is in direct contact with the first pad.

In some implementations, a semiconductor package includes a substrate, first and second semiconductor chips stacked on the substrate, the second semiconductor chip being electrically connected to the substrate through a chip via vertically penetrating the first semiconductor chip, a mold layer provided on the substrate to cover the first and second semiconductor chips, and outer terminals provided below the substrate. The substrate includes an interconnection layer, a passive device disposed on a bottom surface of the interconnection layer, an insulating layer provided on the bottom surface of the interconnection layer to enclose the passive device, substrate pads provided below the passive device, and a connection member disposed at a side of the passive device to connect the interconnection layer to the substrate pads. An active surface of the passive device is in direct contact with the bottom surface of the interconnection layer.

In some implementations, a semiconductor package includes a core layer, an upper interconnection layer provided on a top surface of the core layer, the upper interconnection layer including an insulating pattern and an interconnection pattern, a passive device provided in an internal region, which is formed in the core layer, and electrically connected to the upper interconnection layer, a first semiconductor chip mounted on the upper interconnection layer, the first semiconductor chip including a chip via vertically penetrating the same, a second semiconductor chip stacked on the first semiconductor chip and electrically connected to the upper interconnection layer through the chip via, a mold layer provided on the upper interconnection layer to enclose the first semiconductor chip and the second semiconductor chip, a conductive post disposed on the upper interconnection layer to vertically penetrate the mold layer at a side of the first semiconductor chip, outer pads disposed below the core layer and the passive device and electrically connected to the core layer, and outer terminals provided on the outer pads. The passive device includes first and second electrodes, which are spaced apart from each other, a dielectric material filling a space between the first and second electrodes, and first and second sub-electrodes, which are alternately provided between the first and second electrodes. The first sub-electrodes is connected to the first electrode, and the second sub-electrodes may be connected to the second electrode.

### BRIEF DESCRIPTION OF THE DRAWINGS

FIG. 1 is a sectional view illustrating an example of a semiconductor package.

FIGS. 2 and 3 are enlarged sectional views illustrating an example of a passive device of FIG. 1.

FIGS. 4 and 5 are sectional views illustrating another example of a semiconductor package.

FIGS. 6 and 7 are enlarged sectional views illustrating an example of a passive device of FIG. 5.

FIGS. 8 to 13 are sectional views illustrating another example of a semiconductor package.

FIGS. 14 to 25 are sectional views illustrating an example of a method of fabricating a semiconductor package.

### DETAILED DESCRIPTION

Example implementations will now be described more fully with reference to the accompanying drawings, in which example implementations are shown.

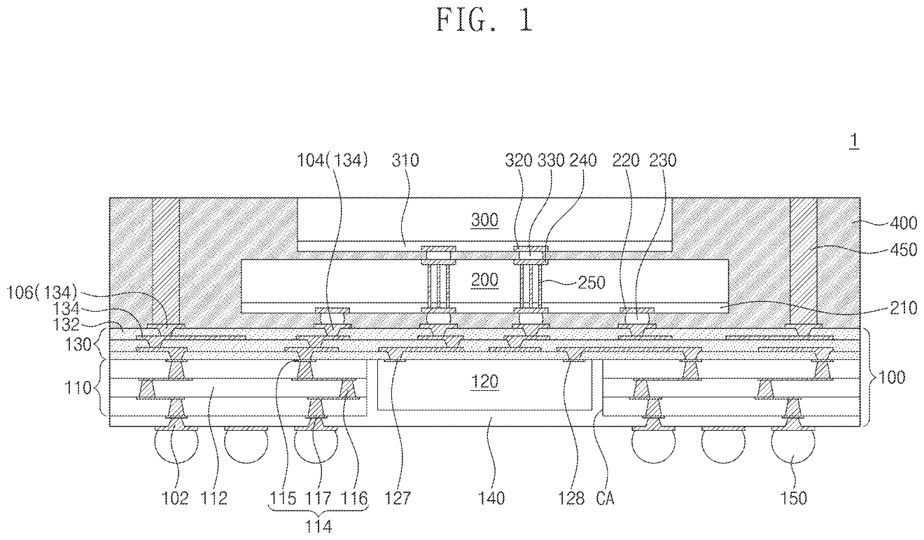

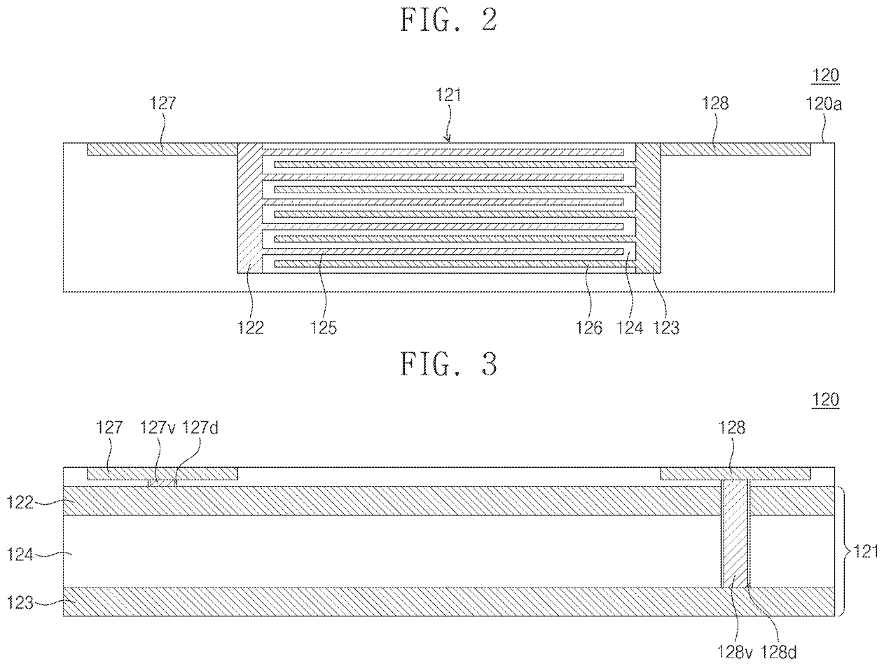

FIG. 1 is a sectional view illustrating an example of a semiconductor package. FIGS. 2 and 3 are enlarged sectional views illustrating an example of a passive device of FIG. 1.

Referring to FIG. 1, a semiconductor package 1 may include a package substrate 100, first and second semiconductor chips 200 and 300, which are mounted on the package substrate 100, and a mold layer 400, which is provided on the package substrate 100 to cover the first and second semiconductor chips 200 and 300.

The package substrate 100 may be provided. The package substrate 100 may include a connection substrate 110, a passive device chip 120 provided in the connection substrate 110, and an upper interconnection layer 130 provided on a top surface of the connection substrate 110.

The connection substrate 110 may be extended in a specific direction. The connection substrate 110 may include one core pattern, which is partially removed when viewed in a plan view. The partially-removed region CA may correspond to an internal region CA, in which the passive device chip 120 is disposed. The connection substrate 110 with one core pattern will be described as an example, but the concept is not limited to this example. In an implementation, the connection substrate 110 may include two or more core patterns. That is, the package substrate 100 may include a plurality of core patterns, which are horizontally spaced apart from each other. The connection substrate 110 may be formed of or include an insulating material. For example, the connection substrate 110 may be formed of or include at least one of glass fibers, ceramic plates, epoxy materials, or resins. Alternatively, the connection substrate 110 may be formed of or include at least one of stainless steel, aluminum (Al), nickel (Ni), magnesium (Mg), zinc (Zn), or tantalum (Ta).

The connection substrate 110 may include a core insulating pattern 112 and a core conductive pattern 114, which is an interconnection pattern provided in the core insulating pattern 112. For example, the core insulating pattern 112 may be formed of or include silicon oxide (SiO₂). The core conductive pattern 114 may be disposed to be spaced apart from the internal region CA. In an implementation, the core conductive pattern 114 may be disposed in an outer region of the connection substrate 110 located outside the internal region CA. The core conductive pattern 114 may include upper core pads 115, core interconnection lines 116, and lower core pads 117. The upper core pads 115 may be provided in an upper portion of the connection substrate 110. The upper core pads 115 may be electrically connected to the upper interconnection layer 130. The lower core pads 117 may be provided on a bottom surface of the connection substrate 110. The core interconnection lines 116 may electrically connect the upper core pads 115 to the lower core pads 117. For example, the core interconnection lines 116 may be vias connecting the upper core pads 115 to the lower core pads 117. Here, a width of the via may decrease in a direction from the bottom surface of the connection substrate 110 toward the top surface of the connection substrate 110. Although not shown, a core protection layer may be provided on the bottom surface of the connection substrate 110 to cover the upper core pads 115. In an implementation, the core protection layer may not be provided. In an implementation, the upper core pads 115 may be exposed to the outside of the connection substrate 110 near the upper surface of the connection substrate 110, as shown in FIG. 1.

FIG. 1 illustrates a structure, in which a plurality of core conductive patterns 114 are stacked to be buried in the core insulating pattern 112, but the concept is not limited to this example. In an implementation, the core insulating pattern 112 of the connection substrate 110 may be provided as a single layer, and in this case, penetration electrodes may be provided to vertically penetrate the core insulating pattern 112 instead of the core conductive pattern 114 of FIG. 1. The penetration electrodes may be extended from the top surface of the core insulating pattern 112 to the bottom surface. The upper core pads 115 may be coupled to top surfaces of the penetration electrodes, and the lower core pads 117 may be coupled to bottom surfaces of the penetration electrodes. The following description will be given based on the implementation of FIG. 1.

The passive device chip 120 may be provided in the internal region CA of the connection substrate 110. The internal region CA may be a region of the connection substrate 110 from which the core pattern is removed. The internal region CA may be an opening, which is formed to penetrate the connection substrate 110. The internal region CA may be exposed the outside of the connection substrate 110 near the top and bottom surfaces of the connection substrate 110. That is, the internal region CA may have a penetration hole shape that is extended from the top surface of the connection substrate 110 toward the bottom surface of the connection substrate 110.

The passive device chip 120 may include a passive device 121 provided therein. In an implementation, the passive device 121 may be a capacitor, a resistor, or an inductor. FIG. 2 illustrates an example of the passive device 121, and for example, the passive device 121 may be a capacitor that is provided in a recess, which is formed in a front surface 120a of the passive device chip 120, as shown in FIG. 2. The passive device 121 may include a first electrode 122 and a second electrode 123, which are provided in the recess and are horizontally spaced apart from each other, and may include a dielectric material 124, which is provided to fill a space between the first and second electrodes 122 and 123.

The first and second electrodes 122 and 123 may be respectively connected to first and second passive device pads 127 and 128 of the passive device chip 120. The first and second passive device pads 127 and 128 may be interconnection lines or pads, which are provided on the front surface 120a of the passive device chip 120. The first and second passive device pads 127 and 128 may be extended from the front surface 120a of the passive device chip 120 toward the recess to be in contact with the first and second electrodes 122 and 123, respectively.

To increase an electrostatic capacitance of the passive device 121, the passive device 121 may further include first sub-electrodes 125 and second sub-electrodes 126, which are alternately provided between the first and second electrodes 122 and 123. The first sub-electrodes 125 may be connected to the first electrode 122, and the second sub-electrodes 126 may be connected to the second electrode 123.

In an implementation, the passive device 121 may be a capacitor, which is formed on the front surface 120a of the passive device chip 120. FIG. 3 illustrates another example of the passive device 121, and in an implementation, the passive device 121 may include the first electrode 122 and the second electrode 123, which are vertically connected to each other, and the dielectric material 124, which is provided to fill a space between the first and second electrodes 122 and 123, as shown in FIG. 3.

The first electrode 122 may be electrically connected to the first passive device pad 127 through a first penetration via 127v, which is provided between the first passive device pad 127 and the first electrode 122. The first penetration via 127v may be extended from a bottom surface of the first passive device pad 127 and may be coupled to a top surface of the first electrode 122. The second electrode 123 may be electrically connected to the second passive device pad 128 through a second penetration via 128v, which is provided between the second passive device pad 128 and the second electrode 123. The second penetration via 128v may be extended from a bottom surface of the second passive device pad 128 to penetrate the first electrode 122 and the dielectric material 124 and may be coupled to a top surface of the second electrode 123. The first and second penetration vias 127v and 128v may be formed of or include a conductive material. Insulating layers 127d and 128d may be provided to enclose outer surfaces of first and second penetration vias 127v and 128v.

So far, some shapes of the passive device 121 have been exemplarily described, but the concept is not limited to this example. In an implementation, the passive device 121 may include capacitors, resistors, or inductors, which are provided in various shapes.

The passive device chip 120 may be spaced apart from an inner side surface of the internal region CA of the connection substrate 110 by a specific distance and may be enclosed by the inner side surface of the internal region CA of the connection substrate 110. That is, the connection substrate 110 may have a shape enclosing the passive device chip 120, when viewed in a plan view. The passive device chip 120 may be provided in a face-up manner. That is, a top surface of the passive device chip 120 may be a front surface. For example, the first passive device pad 127 and the second passive device pad 128 may be provided on the top surface of the passive device chip 120. The top surface of the passive device chip 120 may be located at the same level as the top surface of the connection substrate 110. In an implementation, the top surface of the passive device chip 120 and the top surface of the connection substrate 110 may be placed on the same plane. A thickness of the passive device chip 120 may be equal to or smaller than a thickness of the connection substrate 110. A bottom surface of the passive device chip 120 may be located at a level that is equal to or higher than the bottom surface of the connection substrate 110. That is, the passive device chip 120 may not be extended to a region beyond the bottom surface of the connection substrate 110.

In the internal region CA, a space between the connection substrate 110 and the passive device chip 120 may be filled with an insulating layer 140. The insulating layer 140 may be extended to a region below the passive device chip 120 and below the connection substrate 110. In other words, the insulating layer 140 may cover the bottom surface of the passive device chip 120 and the bottom surface of the connection substrate 110. However, unlike the illustrated structure, the insulating layer 140 may be provided to expose the bottom surface of the passive device chip 120 and the bottom surface of the connection substrate 110. The insulating layer 140 may be formed of or include an insulating polymer. For example, the insulating layer 140 may be formed of or include at least one of thermosetting resins (e.g., epoxy resins), thermoplastic resins (e.g., polyimide), or thermosetting or thermoplastic resins (e.g., ABF, FR-4, BT, and resins) containing reinforcement elements (e.g., inorganic fillers). In addition, a molding material (e.g., EMC) or a photoimageable material (e.g., PIE) may be used for the insulating layer 140.

The upper interconnection layer 130 may cover the top surface of the connection substrate 110. The upper interconnection layer 130 may cover the top surface of the connection substrate 110 and the top surface of the passive device chip 120. The upper interconnection layer 130 may include a plurality of interconnection layers, which are sequentially stacked on the top surface of the connection substrate 110. Each of the interconnection layers may include one upper insulating pattern 132 and an upper interconnection pattern 134, which is provided on the upper insulating pattern 132. That is, the upper interconnection layer 130 may include a plurality of upper insulating patterns 132, which are stacked, and the upper interconnection patterns 134, which are provided between or in the upper insulating patterns 132. The upper interconnection patterns 134 may include circuit patterns. For example, in each interconnection layer, the upper interconnection pattern 134 may include a head portion, which is provided on a top surface of the upper insulating pattern 132 and is horizontally extended, and a via portion, which is extended from a bottom surface of the head portion into the upper insulating pattern 132. The via portion of the upper interconnection pattern 134 may be provided to penetrate the upper insulating pattern 132 and may be coupled to the head portion of the upper interconnection pattern 134 of another interconnection layer thereunder. That is, the head portion may be an element, which is provided in the upper interconnection layer 130 and is used for horizontal interconnection, and the via portion may be an element, which is provided in the upper interconnection layer 130 and is used for vertical interconnection.

The upper interconnection patterns 134 of the lowermost one of the interconnection layers may be connected to the upper core pads 115 of the connection substrate 110 and the first and second passive device pads 127 and 128 of the passive device chip 120. For example, the upper interconnection layer 130 may be in contact with the top surface of the connection substrate 110 and the top surface of the passive device chip 120, and the via portion of the upper interconnection pattern 134 of the lowermost interconnection layer may be provided to penetrate the upper insulating pattern 132 and may be coupled to the upper core pads 115 and the first and second passive device pads 127 and 128.

The upper interconnection patterns 134 of the uppermost one of the interconnection layers may serve as pads of the package substrate 100, on which another device is mounted. For example, the head portion of the upper interconnection pattern 134 of the uppermost interconnection layer may be disposed on the top surface of the upper insulating pattern 132 (in particular, the top surface of the upper interconnection layer 130). That is, the head portion of the upper interconnection pattern 134 of the uppermost interconnection layer may not be covered with the upper insulating pattern 132 and may be exposed to the outside of the upper insulating pattern 132. The head portion of the upper interconnection pattern 134 of the uppermost interconnection layer may be used as first upper substrate pads 104 and second upper substrate pads 106 of the package substrate 100.

The upper insulating patterns 132 may be formed of or include at least one of prepreg, Ajinomoto build-up film (ABF), FR-4, or bismaleimide triazine (BT). The upper interconnection patterns 134 may be formed of or include at least one of copper (Cu), aluminum (Al), silver (Ag), tin (Sn), gold (Au), nickel (Ni), lead (Pb), or titanium (Ti).

The package substrate 100 may further include lower substrate pads 102. The lower substrate pads 102 may be provided on a bottom surface of the package substrate 100. In more detail, the lower substrate pads 102 may be provided on a bottom surface of the insulating layer 140. The lower substrate pads 102 may be provided on the bottom surface of the connection substrate 110 but may not be provided on the bottom surface of the passive device chip 120. The lower substrate pads 102 may be provided on the bottom surface of the connection substrate 110 to penetrate the insulating layer 140 and may be coupled to the lower core pads 117 of the connection substrate 110. That is, the connection substrate 110 may correspond to a vertical connection terminal, which is provided in the package substrate 100 to connect the upper interconnection layer 130 to the lower substrate pads 102.

The package substrate 100 may be provided to have the afore-described structure, but the concept is not limited to this example.

Outer terminals 150 may be disposed below the insulating layer 140. The outer terminals 150 may be provided on the bottom surface of the insulating layer 140. For example, the outer terminals 150 may be provided on the bottom surface of the connection substrate 110 and may not be provided on the bottom surface of the passive device chip 120. Each of the outer terminals 150 may be coupled to a corresponding one of the lower substrate pads 102. Alternatively, unlike the illustrated structure, the package substrate 100 may not include the lower substrate pads 102, and the outer terminals 150 may be provided on the bottom surface of the connection substrate 110 to penetrate the insulating layer 140 and may be coupled to the lower core pads 117 of the connection substrate 110. The following description will be given based on the implementation of FIG. 1. The outer terminals 150 may include solder balls or solder bumps.

The first semiconductor chip 200 may be mounted on the package substrate 100. The first semiconductor chip 200 may include a semiconductor material (e.g., silicon (Si)). The first semiconductor chip 200 may include a first circuit layer 210. The first circuit layer 210 of the first semiconductor chip 200 may include a logic circuit. In other words, the first semiconductor chip 200 may be logic chip. The first circuit layer 210 may be provided on a bottom surface of the first semiconductor chip 200. The bottom surface of the first semiconductor chip 200 may be a front surface of the first semiconductor chip 200, and a top surface of the first semiconductor chip 200 may be a rear surface of the first semiconductor chip 200. FIG. 1 illustrates an example, in which one first semiconductor chip 200 is provided, but the concept is not limited to this example. In an implementation, a plurality of first semiconductor chips 200 may be provided. In this case, the first semiconductor chips 200 may be disposed on the package substrate 100 to be horizontally spaced apart from each other. The first semiconductor chip 200 may be mounted on the package substrate 100 in a flip chip manner. For example, the first semiconductor chip 200 may be disposed on the package substrate 100 to have a front surface facing the package substrate 100. First chip pads 220 may be provided on a surface of the first circuit layer 210 of the first semiconductor chip 200, and first chip terminals 230 may be provided on the first chip pads 220. The first chip terminals 230 may be coupled to the first upper substrate pads 104 of the upper interconnection layer 130. For example, the first chip terminals 230 may connect the first upper substrate pads 104 to the first chip pads 220. Here, the first semiconductor chip 200 may be connected to the passive device chip 120 through the upper interconnection layer 130.

The first semiconductor chip 200 may further include second chip pads 240 and chip vias 250. The second chip pads 240 may be provided on the top surface of the first semiconductor chip 200. The chip vias 250 may be provided to vertically penetrate the first semiconductor chip 200. The chip vias 250 may be extended toward the top surface of the first semiconductor chip 200 and may be coupled to the second chip pads 240. The chip vias 250 may be extended toward the bottom surface of the first semiconductor chip 200 and may be coupled to the first chip pads 220 or the first circuit layer 210. That is, the chip vias 250 may correspond to a vertical interconnection structure connecting the first chip pads 220 or the first circuit layer 210 to the second chip pads 240.

The second semiconductor chip 300 may be stacked on the first semiconductor chip 200. The second semiconductor chip 300 may be mounted on the first semiconductor chip 200. The second semiconductor chip 300 may include a semiconductor material (e.g., silicon (Si)). The second semiconductor chip 300 may include a second circuit layer 310. The second circuit layer 310 of the second semiconductor chip 300 may include a memory circuit. In other words, the second semiconductor chip 300 may be a memory chip. The second circuit layer 310 may be provided on a bottom surface of the second semiconductor chip 300. That is, the bottom surface of the second semiconductor chip 300 may be a front surface of the second semiconductor chip 300, and a top surface of the second semiconductor chip 300 may be a rear surface of the second semiconductor chip 300. FIG. 1 illustrates an example, in which one second semiconductor chip 300 is provided, but the concept is not limited to this example. In an implementation, a plurality of second semiconductor chips 300 may be provided. In this case, the second semiconductor chips 300 may be vertically stacked on the package substrate 100 to have a chip stack structure. The second semiconductor chip 300 may be mounted on the first semiconductor chip 200 in a flip chip manner. For example, the second semiconductor chip 300 may be disposed on the first semiconductor chip 200 to have a front surface facing the first semiconductor chip 200. Third chip pads 320 may be disposed on a surface of the second circuit layer 310 of the second semiconductor chip 300, and second chip terminals 330 may be provided on the third chip pads 320. The second chip terminals 330 may be coupled to the second chip pads 240 of the first semiconductor chip 200. For example, the second chip terminals 330 may connect the second chip pads 240 to the third chip pads 320. Here, the second semiconductor chip 300 may be connected to the lower substrate pads 102 of the package substrate 100 or the passive device chip 120 through the chip vias 250 of the first semiconductor chip 200.

In some implementations, the semiconductor package 1 may be provided to include the package substrate 100, and the passive device chip 120 may be embedded in the package substrate 100. Thus, an additional space for mounting the passive device chip 120 on the package substrate 100 may not be required, and this may make it possible to reduce a size of the semiconductor package 1. In addition, an additional space for mounting the passive device chip 120 below the package substrate 100 may not be required, and thus, the lower substrate pads 102 may be more freely disposed on the bottom surface of the package substrate 100. Furthermore, since the first and second semiconductor chips 200 and 300 are electrically connected to the passive device chip 120 through only the upper interconnection layer 130 of the package substrate 100, a length of an electric connection path between the first and second semiconductor chips 200 and 300 and the passive device chip 120 may be short, and in this case, the electrical characteristics of the semiconductor package 1 may be improved.

The mold layer 400 may be provided on the package substrate 100. The mold layer 400 may be provided on the top surface of the package substrate 100 to cover the first and second semiconductor chips 200 and 300. The mold layer 400 may include an insulating material. For example, the mold layer 400 may be formed of or include an epoxy molding compound (EMC).

Substrate posts 450 may be provided on the package substrate 100. The substrate posts 450 may be disposed on the package substrate 100 and around the first and second semiconductor chips 200 and 300. The substrate posts 450 may be provided to vertically penetrate the mold layer 400. The substrate posts 450 may be extended toward a top surface of the mold layer 400 and may be exposed to the outside of the mold layer 400 near the top surface of the mold layer 400. Top surfaces of the substrate posts 450 may be coplanar with the top surface of the mold layer 400. The substrate posts 450 may be extended toward a bottom surface of the mold layer 400 and may be coupled to the second upper substrate pads 106 of the package substrate 100. The substrate posts 450 may be a vertical interconnection structure that is used to electrically connect another package or other devices, which are mounted on the semiconductor package 1, to the semiconductor package 1. In an implementation, the substrate posts 450 may be a heat transferring structure that is used to dissipate heat, which is generated in the semiconductor package 1, to a region on the semiconductor package 1. The substrate posts 450 may be formed of or include a metallic material. For example, the substrate posts 450 may be formed of or include at least one of copper (Cu), tungsten (W), titanium (Ti), nickel (Ni), or gold (Au).

The semiconductor package may have the same structure as the semiconductor package 1.

In the description of the implementations to be explained below, an element previously described with reference to FIGS. 1 to 3 may be identified by the same reference number without repeating an overlapping description thereof, for concise description.

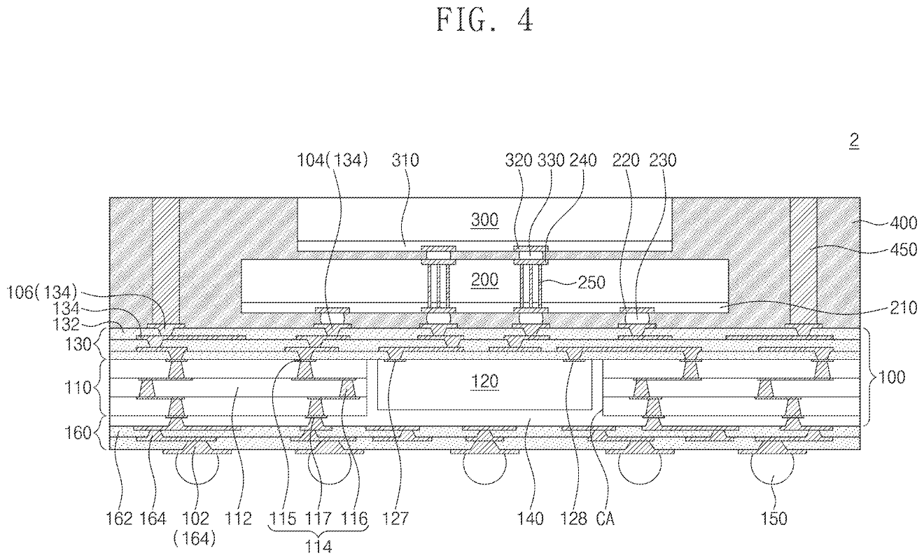

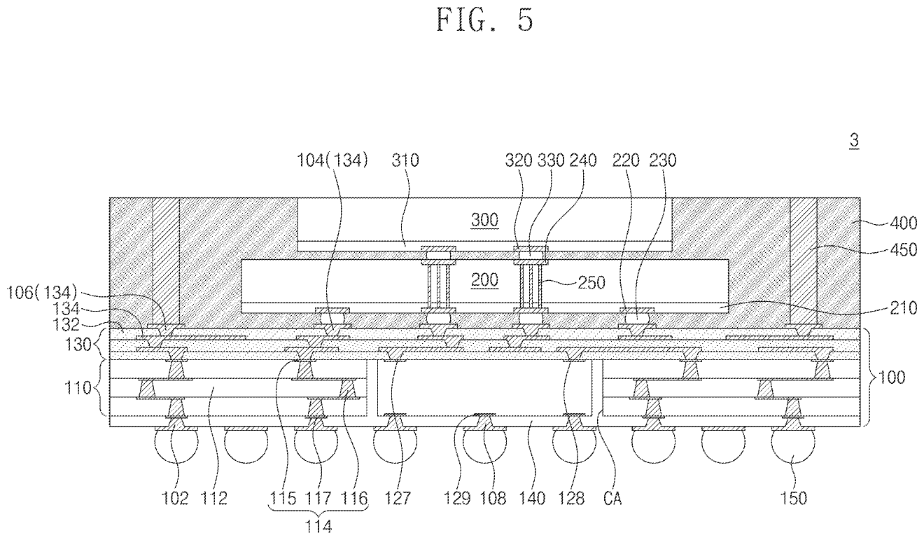

FIG. 4 is a sectional view illustrating another example of a semiconductor package.

Referring to FIG. 4, the package substrate 100 of a semiconductor package 2 may further include a lower interconnection layer 160.

The lower interconnection layer 160 may cover the bottom surface of the insulating layer 140. The lower interconnection layer 160 may include a plurality of interconnection layers, which are sequentially stacked on the bottom surface of the insulating layer 140. Each of the interconnection layers may include one lower insulating pattern 162 and a lower interconnection pattern 164 provided on the lower insulating pattern 162. That is, the lower interconnection layer 160 may include a plurality of lower insulating patterns 162, which are stacked, and the lower interconnection patterns 164, which are provided between or in the lower insulating patterns 162. The lower interconnection pattern 164 may include a circuit pattern. For example, in each interconnection layer, the lower interconnection pattern 164 may include a head portion, which is provided on a bottom surface of the lower insulating pattern 162 and is horizontally extended, and a via portion, which is extended from a top surface of the head portion into the lower insulating pattern 162. The via portion of the lower interconnection pattern 164 may be provided to penetrate the lower insulating pattern 162 and may be coupled to the head portion of the lower interconnection pattern 164 of another interconnection layer thereon. That is, the head portion may be an element, which is provided in the lower interconnection layer 160 and is used for horizontal interconnection, and the via portion may be an element, which is provided in the lower interconnection layer 160 and is used for vertical interconnection.

The lower interconnection pattern 164 of the uppermost one of the interconnection layers may be connected to the lower core pads 117 of the connection substrate 110. For example, the lower interconnection layer 160 may be in contact with the bottom surface of the insulating layer 140, and the via portion of the lower interconnection pattern 164 of the uppermost interconnection layer may be provided to penetrate a portion of the insulating layer 140, which is interposed between the lower interconnection layer 160 and the connection substrate 110, and may be coupled to the lower core pads 117.

The lower interconnection pattern 164 of the lowermost one of the interconnection layers may be pads, which are used to mount the semiconductor package 2 or the package substrate 100 on another substrate, a motherboard, or a device. For example, the head portion of the lower interconnection pattern 164 of the lowermost interconnection layer may be disposed on the bottom surface of the lower insulating pattern 162 (in particular, a bottom surface of the lower interconnection layer 160). That is, the head portion of the lower interconnection pattern 164 of the lowermost interconnection layer may not be covered with the lower insulating pattern 162 and may be exposed to the outside of the lower insulating pattern 162. The head portion of the lower interconnection pattern 164 of the lowermost interconnection layer may be used as the lower substrate pads 102 of the package substrate 100. The lower substrate pads 102 may be provided on the bottom surface of the lower interconnection layer 160 or on the bottom surface of the passive device chip 120.

The lower insulating pattern 162 may be formed of or include at least one of prepreg, Ajinomoto build-up film (ABF), FR-4, or bismaleimide triazine (BT). The lower interconnection pattern 164 may be formed of or include at least one of copper (Cu), aluminum (Al), silver (Ag), tin (Sn), gold (Au), nickel (Ni), lead (Pb), or titanium (Ti).

The outer terminals 150 may be disposed below the lower interconnection layer 160. The outer terminals 150 may be provided on the bottom surface of the lower interconnection layer 160. For example, the outer terminals 150 may be provided on the bottom surface of the lower interconnection layer 160 or on the bottom surface of the passive device chip 120. Each of the outer terminals 150 may be coupled to a corresponding one of the lower substrate pads 102. Alternatively, unlike the illustrated structure, the package substrate 100 may not include the lower substrate pads 102, and the outer terminals 150 may be provided to penetrate the lower insulating pattern 162 of the lowermost interconnection layer of the lower interconnection layer 160 and may be coupled to the lower interconnection patterns 164 of the lower interconnection layer 160.

In some implementations, the lower interconnection layer 160 may be disposed below the package substrate 100, and thus, the lower substrate pads 102 may be disposed more freely. In this case, it may be possible to easily form an interconnection structure and improve the electrical characteristics of the semiconductor package 1.

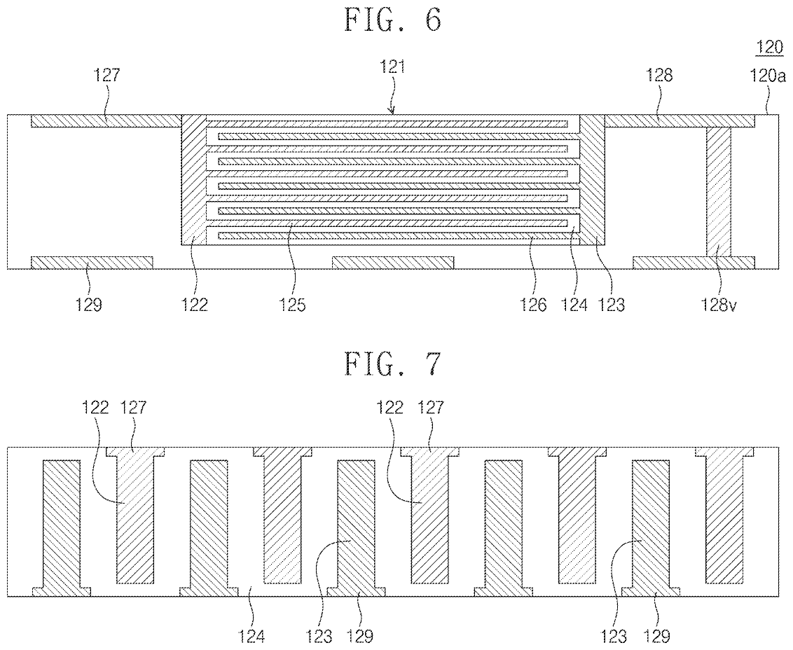

FIG. 5 is a sectional view illustrating another example of a semiconductor package. FIGS. 6 and 7 are enlarged sectional views illustrating an example of a passive device of FIG. 5.

Referring to FIG. 5, the passive device chip 120 of a semiconductor package 3 may further include third passive device pads 129. The third passive device pads 129 may be interconnection lines or pads, which are formed in a rear surface of the passive device chip 120.

FIG. 6 illustrates an example of the passive device 121, and the passive device 121 may be a capacitor that is provided in a recess formed in the front surface 120a of the passive device chip 120, as shown in FIG. 6. The passive device 121 of FIG. 6 may further include the third passive device pads 129 and the second penetration via 128v, similar to the passive device 121 of FIG. 2. The third passive device pad 129 may be electrically connected to the second passive device pad 128 through the second penetration via 128v, which is provided between the second passive device pad 128 and the third passive device pads 129. The second penetration via 128v may be provided around the passive device 121 to vertically penetrate the passive device chip 120 and connect the second passive device pad 128 to the third passive device pads 129.

FIG. 7 illustrates an example of the passive device, and in an implementation, the passive device may include the first electrodes 122, which are pillar-shaped patterns extended from the top surface of the passive device chip 120 into the passive device chip 120, the second electrodes 123, which are pillar-shaped patterns extended from the bottom surface of the passive device chip 120 into the passive device chip 120, and the dielectric material 124, which is provided to fill a space between the first electrodes 122 and the second electrodes 123, as shown in FIG. 7. Portions of the first electrodes 122, which are exposed to the outside of the passive device chip 120 near the top surface of the passive device chip 120, may serve as the first passive device pads 127 of the passive device chip 120, and portions of the second electrodes 123, which are exposed to the outside of the passive device chip 120 near the bottom surface of the passive device chip 120, may serve as the third passive device pads 129 of the passive device chip 120.

Referring back to FIG. 5, the top surface of the passive device chip 120 may be located at the same level as the top surface of the connection substrate 110. In an implementation, the top surface of the passive device chip 120 and the top surface of the connection substrate 110 may be placed on the same plane. A thickness of the passive device chip 120 may be substantially equal to or smaller than a thickness of the connection substrate 110. The bottom surface of the passive device chip 120 may be located at substantially the same level as the bottom surface of the connection substrate 110.

The lower substrate pads 102 may be provided on the bottom surface of the package substrate 100. In more detail, the lower substrate pads 102 may be provided on the bottom surface of the insulating layer 140. The lower substrate pads 102 may be provided on the bottom surface of the connection substrate 110 or on the bottom surface of the passive device chip 120. The lower substrate pads 102 on the bottom surface of the connection substrate 110 may be provided to penetrate the insulating layer 140 and may be coupled to the lower core pads 117 of the connection substrate 110, and the lower substrate pads 102 on the bottom surface of the passive device chip 120 may be provided to penetrate the insulating layer 140 and may be coupled to the third passive device pads 129 of the passive device chip 120.

In some implementations, the passive device chip 120 may be directly connected to the lower substrate pads 102, and a length of an electric connection path between the passive device chip 120 and the lower substrate pads 102 may be reduced. That is, the semiconductor package may be provided to have improved electrical characteristics.

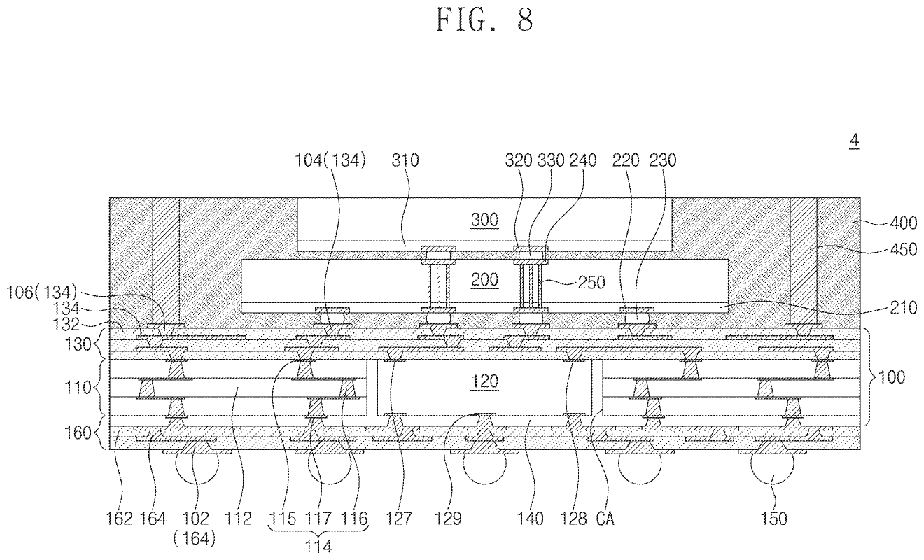

FIG. 8 is a sectional view illustrating another example of a semiconductor package.

Referring to FIG. 8, the package substrate 100 of a semiconductor package 4 may further include the lower interconnection layer 160.

The lower interconnection layer 160 of the semiconductor package 4 may be substantially the same as or similar to the lower interconnection layer 160 of the semiconductor package 2 described with reference to FIG. 4. For example, the lower interconnection layer 160 may cover the bottom surface of the insulating layer 140. The lower interconnection layer 160 may include a plurality of interconnection layers, which are sequentially stacked on the bottom surface of the insulating layer 140. Each of the interconnection layers may include one lower insulating pattern 162 and the lower interconnection pattern 164 provided on the lower insulating pattern 162. In each interconnection layer, the lower interconnection pattern 164 may include a head portion, which is provided on the bottom surface of the lower insulating pattern 162 and is horizontally extended, and a via portion, which is extended from a top surface of the head portion into the lower insulating pattern 162.

The lower interconnection pattern 164 of the uppermost one of the interconnection layers of the lower interconnection layer 160 may be connected to the lower core pads 117 of the connection substrate 110. For example, the lower interconnection layer 160 may be in contact with the bottom surface of the insulating layer 140, and the via portion of the lower interconnection pattern 164 of the uppermost interconnection layer may be provided to penetrate a portion of the insulating layer 140, which is interposed between the lower interconnection layer 160 and the connection substrate 110, and may be coupled to the lower core pads 117.

In addition, the lower interconnection pattern 164 of the uppermost interconnection layer may be connected to the third passive device pads 129 of the passive device chip 120. For example, the lower interconnection layer 160 may be in contact with the bottom surface of the insulating layer 140, and the via portion of the lower interconnection pattern 164 of the uppermost interconnection layer may be provided to penetrate a portion of the insulating layer 140, which is interposed between the lower interconnection layer 160 and the passive device chip 120, and may be coupled to the third passive device pads 129.

The outer terminals 150 may be coupled to the lower substrate pads 102 of the lower interconnection layer 160.

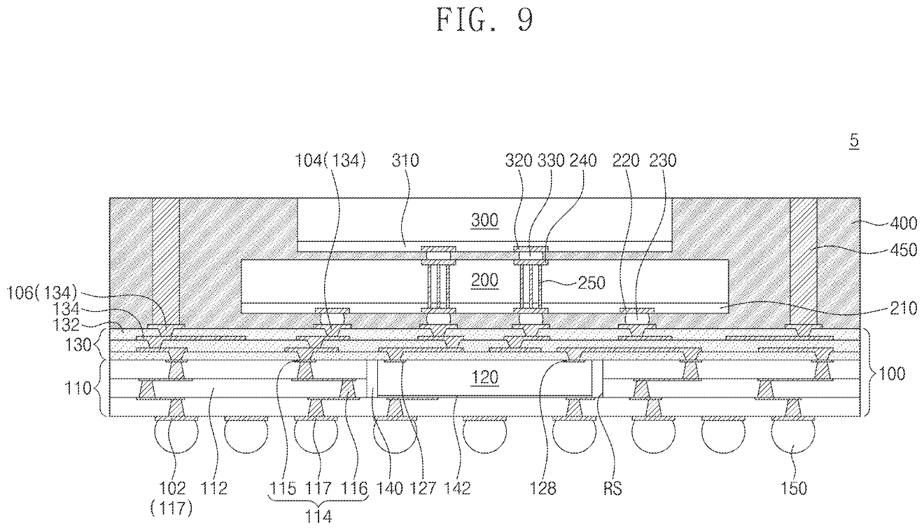

FIG. 9 is a sectional view illustrating another example of a semiconductor package.

Referring to FIG. 9, the connection substrate 110 of the package substrate 100 of a semiconductor package 5 may have an internal region RS, which is provided in the form of a vertically-recessed upper portion of the connection substrate 110, not in the form of an opening penetrating the connection substrate 110. The internal region RS may have a recess shape that is extended from the top surface of the connection substrate 110 into the connection substrate 110. In this case, a bottom surface of the internal region RS may correspond to a top surface of one of the interconnection layers of the connection substrate 110.

The passive device chip 120 may be provided in the internal region RS of the connection substrate 110. In an implementation, the passive device chip 120 may be disposed in the internal region RS and may be attached to the internal region RS using an adhesive layer 142. The adhesive layer 142 may be interposed between the rear surface of the passive device chip 120 and the bottom surface of the internal region RS. That is, the passive device chip 120 may be provided in a face-up manner, and the top surface of the passive device chip 120 may be a front surface. For example, the first passive device pad 127 and the second passive device pad 128 may be provided on the top surface of the passive device chip 120. The passive device chip 120 may be spaced apart the inner side surface of the internal region RS of the connection substrate 110 by a specific distance and may be enclosed by the inner side surface of the internal region RS of the connection substrate 110.

In the internal region RS, a space between the connection substrate 110 and the passive device chip 120 may be filled with the insulating layer 140. A top surface of the insulating layer 140 may be located at the same level as the top surface of the passive device chip 120 and the top surface of the connection substrate 110. In an implementation, the top surface of the insulating layer 140, the top surface of the passive device chip 120, and the top surface of the connection substrate 110 may be placed on the same plane.

The upper interconnection layer 130 may cover the top surface of the connection substrate 110. The upper interconnection layer 130 may cover the top surface of the connection substrate 110 and the top surface of the passive device chip 120. The upper interconnection layer 130 may include a plurality of interconnection layers, which are sequentially stacked on the top surface of the connection substrate 110. Each of the interconnection layers may include one upper insulating pattern 132 and the upper interconnection pattern 134, which is provided on the upper insulating pattern 132. In each interconnection layer, the upper interconnection pattern 134 may include a head portion, which is provided on the top surface of the upper insulating pattern 132 and is horizontally extended, and a via portion, which is extended from a bottom surface of the head portion into the upper insulating pattern 132. The upper interconnection patterns 134 of the lowermost one of the interconnection layers may be connected to the upper core pads 115 of the connection substrate 110 and the first and second passive device pads 127 and 128 of the passive device chip 120.

The lowermost one of the interconnection layers of the connection substrate 110 may be disposed below the passive device chip 120. Thus, the core conductive pattern 114 of the lowermost interconnection layer may be disposed below the passive device chip 120. The lower core pads 117 of the connection substrate 110 may correspond to the lower substrate pads 102 of the package substrate 100. For example, the lower core pads 117 may be exposed to the outside of the package substrate 100 near the bottom surface of the package substrate 100, and the outer terminals 150 may be provided on the lower core pads 117. That is, the lowermost interconnection layer of the connection substrate 110 may serve as a lower interconnection layer.

In some implementations, since the insulating layer 140 does not cover the bottom surface of the connection substrate 110, the lower core pads 117 of the connection substrate 110 may be exposed to the outside, and the lower core pads 117 may be used as the lower substrate pads 102 of the package substrate 100. It may be possible to reduce a length of an electric connection path between the connection substrate 110 and the outer terminals 150 and simplify an electric interconnection structure in the package substrate 100. That is, the semiconductor package may be provided to have improved electrical characteristics and a simplified structure.

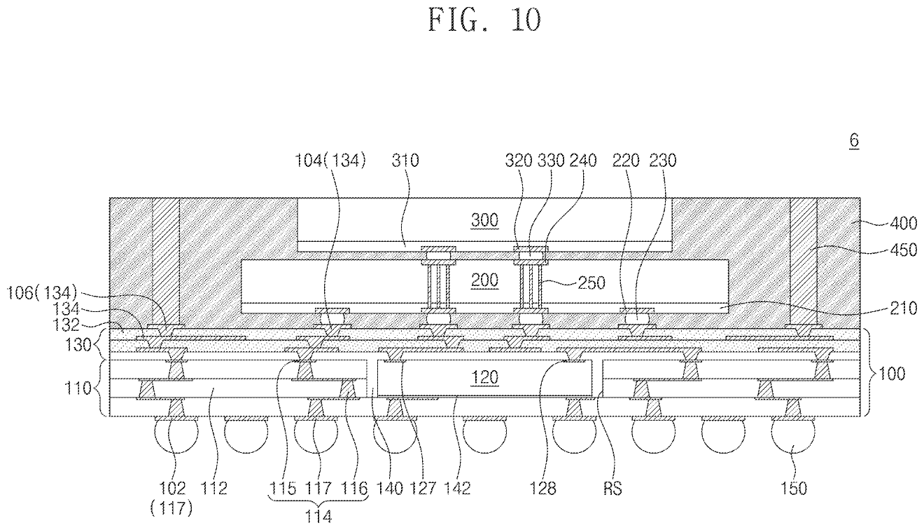

FIG. 10 is a sectional view illustrating another example of a semiconductor package.

Referring to FIG. 10, the insulating layer 140 of a semiconductor package 6 of FIG. 10 may be extended to a region on the passive device chip 120 and on the connection substrate 110, unlike the semiconductor package 5 of FIG. 9. In other words, the insulating layer 140 may cover the top surface of the passive device chip 120 and the top surface of the connection substrate 110.

The upper interconnection layer 130 may cover the top surface of the insulating layer 140. In other words, the upper interconnection layer 130 may be spaced apart from the passive device chip 120 and the connection substrate 110 by the insulating layer 140.

The upper interconnection patterns 134 of the lowermost one of the interconnection layers of the upper interconnection layer 130 may be connected to the upper core pads 115 of the connection substrate 110 and the first and second passive device pads 127 and 128 of the passive device chip 120. For example, the upper interconnection layer 130 may be in contact with the top surface of the insulating layer 140. The via portion of the upper interconnection pattern 134 of the lowermost interconnection layer, which is placed on the connection substrate 110, may be provided to penetrate the insulating layer 140 and may be coupled to the upper core pad 115. The via portions of the upper interconnection patterns 134 of the lowermost interconnection layer, which are placed on the passive device chip 120, may be provided to penetrate the insulating layer 140 and may be coupled to the first and second passive device pads 127 and 128.

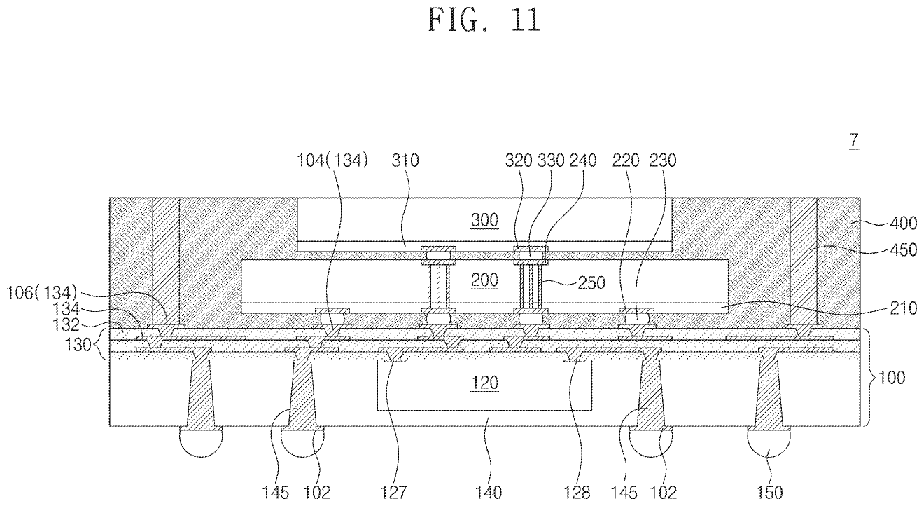

FIG. 11 is a sectional view illustrating another example of a semiconductor package.

Referring to FIG. 11, a semiconductor package 7 may include the package substrate 100, the first and second semiconductor chips 200 and 300 mounted on the package substrate 100, and the mold layer 400 provided on the package substrate 100 to cover the first and second semiconductor chips 200 and 300.

The package substrate 100 may be provided. The package substrate 100 may include the passive device chip 120 and the upper interconnection layer 130, which is disposed on the passive device chip 120.

The passive device chip 120 and the upper interconnection layer 130 may be substantially the same as or similar to those in the implementations described with reference to FIGS. 1 to 10. For example, the passive device chip 120 may include a passive device provided therein, and the first and second passive device pads 127 and 128 may be provided on the top surface of the passive device chip 120. The upper interconnection layer 130 may include the upper insulating patterns 132 and the upper interconnection patterns 134, which are sequentially stacked on the passive device chip 120. The upper interconnection patterns 134 may be connected to the first and second passive device pads 127 and 128 of the passive device chip 120.

The insulating layer 140 may be disposed on a bottom surface of the upper interconnection layer 130 to enclose the passive device chip 120. The insulating layer 140 may be provided on the bottom surface of the upper interconnection layer 130 to bury the passive device chip 120. That is, the insulating layer 140 may cover the bottom surface of the upper interconnection layer 130 and the side and bottom surfaces of the passive device chip 120. The insulating layer 140 may be in contact with the side and bottom surfaces of the passive device chip 120. Accordingly, the passive device chip 120 may not be exposed to the outside of the insulating layer 140. The insulating layer 140 may be formed of or include an insulating material (e.g., an epoxy molding compound (EMC)). Alternatively, the insulating layer 140 may be formed of or include an insulating polymer. For example, the insulating layer 140 may be formed of or include at least one of thermosetting resins (e.g., epoxy resins), thermoplastic resins (e.g., polyimide), or thermosetting or thermoplastic resins (e.g., ABF, FR-4, BT, and resins) containing reinforcement elements (e.g., inorganic fillers). In addition, a molding material (e.g., EMC) or a photoimageable material (e.g., PIE) may be used for the insulating layer 140.

Penetration electrodes 145 may be disposed in the insulating layer 140. The penetration electrodes 145 may be disposed around the passive device chip 120 to vertically penetrate the insulating layer 140. A width of the penetration electrode 145 may decrease as a distance to the upper interconnection layer 130 decreases. The penetration electrodes 145 may be provided to penetrate the insulating layer 140 and may be exposed to the outside of the insulating layer 140 near the top surface of the insulating layer 140. The upper interconnection patterns 134 of the upper interconnection layer 130 may be provided to penetrate the upper insulating patterns 132 and be in contact with top surfaces of the penetration electrodes 145. The penetration electrodes 145 may be provided to penetrate the insulating layer 140 and may be exposed to the outside of the insulating layer 140 near the bottom surface of the insulating layer 140.

The lower substrate pads 102 may be disposed on bottom surfaces of the penetration electrodes 145. The lower substrate pads 102 may be in contact with the bottom surfaces of the penetration electrodes 145. Here, at least one of the lower substrate pads 102 may form a single object with a corresponding one of the penetration electrodes 145 in contact with the same. In other words, the lower substrate pad 102 may be a portion of the penetration electrode 145 extended to a region under the bottom surface of the insulating layer 140.

The outer terminals 150 may be disposed below the insulating layer 140. Each of the outer terminals 150 may be coupled to a corresponding one of the lower substrate pads 102.

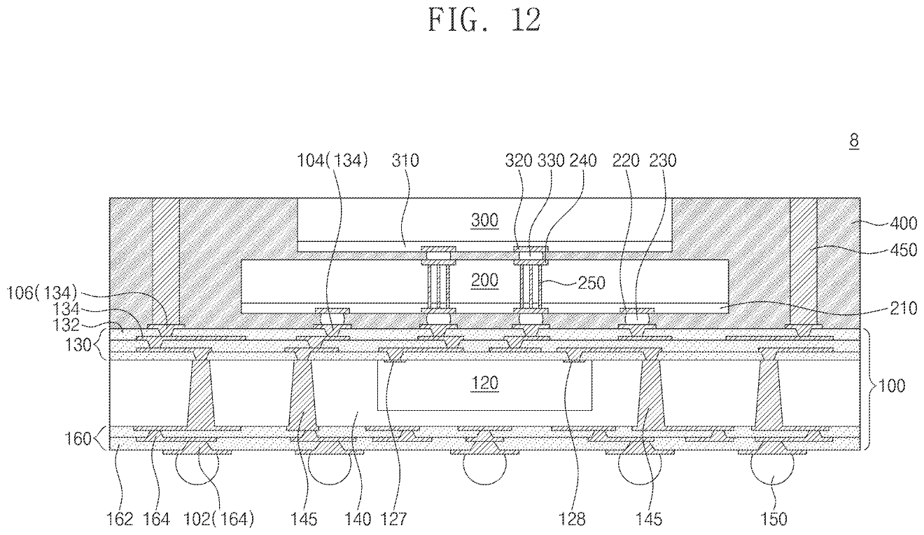

FIG. 12 is a sectional view illustrating another example of a semiconductor package.

Referring to FIG. 12, the package substrate 100 of a semiconductor package 8 of FIG. 12 may further include the lower interconnection layer 160, unlike the semiconductor package 7 of FIG. 11. The lower interconnection layer 160 may be substantially the same as or similar to the lower interconnection layer 160 of the semiconductor package 2 described with reference to FIG. 4. For example, the lower interconnection layer 160 may include a plurality of interconnection layers, which are sequentially stacked. Each of the interconnection layers may include one lower insulating pattern 162 and the lower interconnection pattern 164 provided on the lower insulating pattern 162. In each interconnection layer, the lower interconnection pattern 164 may include a head portion, which is provided on the bottom surface of the lower insulating pattern 162 and is horizontally extended, and a via portion, which is extended from a top surface of the head portion into the lower insulating pattern 162.

The lower interconnection layer 160 may be disposed on the bottom surface of the insulating layer 140. The penetration electrodes 145 may be provided to penetrate the insulating layer 140 and may be exposed to the outside of the insulating layer 140 near the bottom surface of the insulating layer 140. The lower interconnection patterns 164 of the uppermost one of the interconnection layers of the lower interconnection layer 160 may be in contact with bottom surfaces of the penetration electrodes 145. Here, at least one of the lower interconnection patterns 164 may form a single object with a corresponding one of the penetration electrodes 145 in contact with the same.

The lower interconnection pattern 164 of the lowermost one of the interconnection layers may be pads, which are used to mount the semiconductor package 8 or the package substrate 100 on another substrate, a motherboard, or a device. The head portion of the lower interconnection pattern 164 of the lowermost interconnection layer may be used as the lower substrate pads 102 of the package substrate 100.

The outer terminals 150 may be disposed below the lower interconnection layer 160. Each of the outer terminals 150 may be coupled to a corresponding one of the lower substrate pads 102.

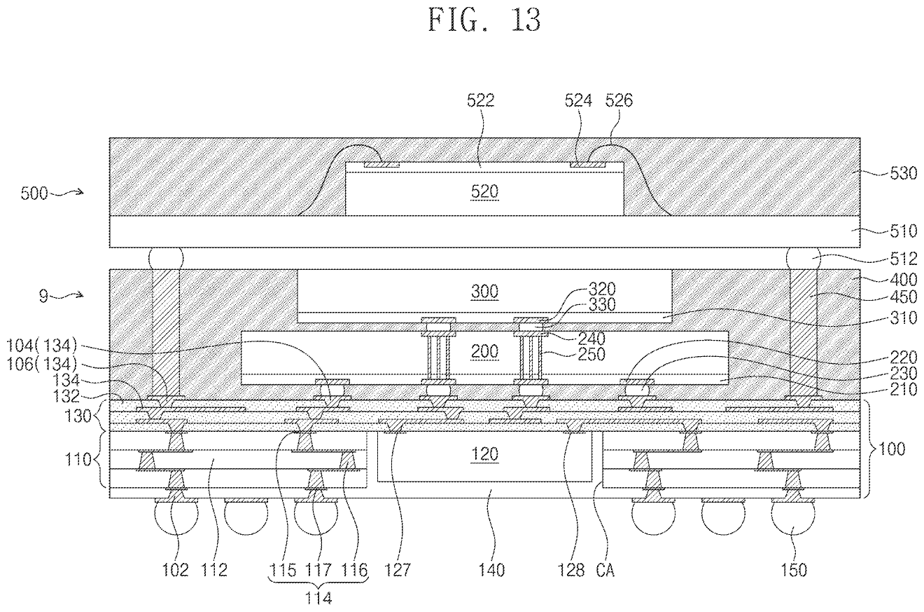

FIG. 13 is a sectional view illustrating another example of a semiconductor package.

Referring to FIG. 13, a lower package 9 may be provided. The lower package 9 may be one of the semiconductor packages 1, 2, 3, 4, 5, 6, 7, and 8 described with reference to FIGS. 1 to 12.

The semiconductor package may further include an upper package 500 provided on the lower package 9. That is, the semiconductor package according to the implementation of FIG. 13 may be provided to have a package-on-package structure.

The upper package 500 may include an upper substrate 510, an upper semiconductor chip 520, and an upper mold layer 530.

The upper substrate 510 may be a printed circuit board (PCB). Alternatively, the upper substrate 510 may be a redistribution substrate or a redistribution layer. The upper substrate 510 may have lower substrate pads, which are provided on a bottom surface of the upper substrate 510, and upper substrate pads, which are provided on a top surface of the upper substrate 510.

The upper semiconductor chip 520 may be disposed on the upper substrate 510. The upper semiconductor chip 520 may include a semiconductor material (e.g., silicon (Si)). The upper semiconductor chip 520 may include a third circuit layer 522. The third circuit layer 522 of the upper semiconductor chip 520 may be a logic chip or a memory chip. The third circuit layer 522 may be provided on a top surface of the upper semiconductor chip 520. In other words, the top surface of the upper semiconductor chip 520 may be a front surface of the upper semiconductor chip 520. FIG. 13 illustrates an example, in which one upper semiconductor chip 520 is provided, but the concept is not limited to this example. In an implementation, a plurality of upper semiconductor chips 520 may be provided. In this case, the upper semiconductor chips 520 may be disposed such that they are horizontally spaced apart from each other on the upper substrate 510 and are stacked on the upper substrate 510. The upper semiconductor chip 520 may be mounted on the upper substrate 510 in a wire bonding manner. For example, fourth chip pads 524 may be provided on a surface of the third circuit layer 522 of the upper semiconductor chip 520, and bonding wires 526 may be provided on the fourth chip pads 524. The bonding wires 526 may be coupled to the upper substrate pads of the upper substrate 510.

The upper mold layer 530 may be provided on the upper substrate 510. The upper mold layer 530 may be provided on the upper substrate 510 to cover the upper semiconductor chip 520. The upper mold layer 530 may include an insulating material (e.g., an epoxy molding compound (EMC)).

The upper package 500 may be mounted on the lower package 9. In detail, package connection terminals 512 may be provided between the upper package 500 and the lower package 9. The connection terminals 512 may connect the lower substrate pads of the upper substrate 510 to the substrate posts 450 of the lower package 9. Alternatively, various structures (e.g., pads) may be provided on the mold layer 400 of the lower package 9 to connect the upper substrate 510 to the substrate posts 450. The upper package 500 may be electrically connected to the outer terminals 150 through the substrate posts 450 and the package substrate 100.

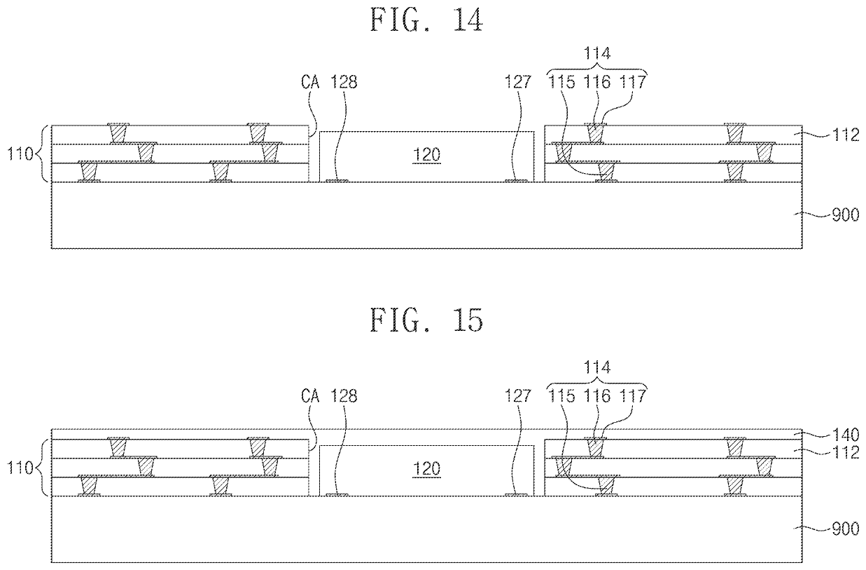

FIGS. 14 to 20 are sectional views illustrating an example of a method of fabricating a semiconductor package.

Referring to FIG. 14, the connection substrate 110 may be provided. The connection substrate 110 may be the same as or similar to the connection substrate 110 described with reference to FIGS. 1 to 8. For example, the connection substrate 110 may include the core insulating pattern 112 and the core conductive pattern 114. The core conductive pattern 114 may include the upper core pads 115, the core interconnection lines 116, and the lower core pads 117. A first carrier substrate 900 may be attached to the bottom surface of the connection substrate 110. The first carrier substrate 900 may be an insulating substrate containing glass or polymeric materials or a conductive substrate containing a metallic material. The first carrier substrate 900 may be attached to the core insulating pattern 112 and the upper core pads 115 of the connection substrate 110 using an adhesive member provided on a top surface thereof. In an implementation, the adhesive member may include an adhesive tape.

The internal region CA may be formed in the connection substrate 110. The internal region CA may be formed by removing a portion of the connection substrate 110 to penetrate the connection substrate 110. For example, the internal region CA may be formed by performing an etching process, such as a drilling process, a laser ablation process, or a laser cutting process. The removed portion of the connection substrate 110 may be a space, in which the passive device chip 120 will be provided in a subsequent process.

The passive device chip 120 may be provided on the first carrier substrate 900. The passive device chip 120 may be disposed in the internal region CA of the connection substrate 110. The passive device chip 120 may be attached to the first carrier substrate 900. Here, the passive device chip 120 may be attached to the first carrier substrate 900 such that the first and second passive device pads 127 and 128 face the first carrier substrate 900.

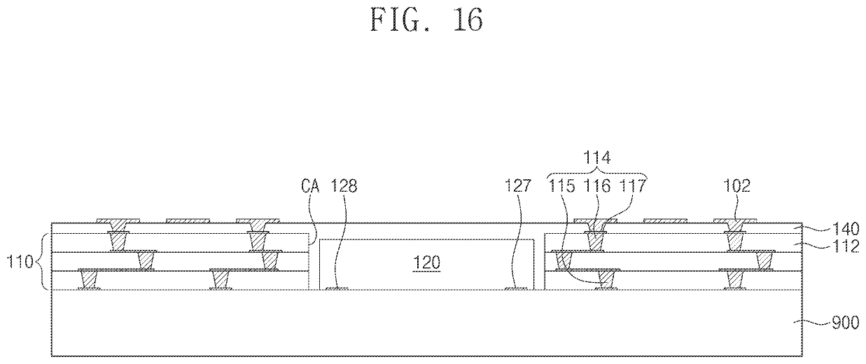

Referring to FIG. 15, the insulating layer 140 may be formed on the first carrier substrate 900. The insulating layer 140 may be provided to fill a space between the connection substrate 110 and the passive device chip 120. For example, the insulating layer 140 may be formed by injecting an insulating material into the space between the connection substrate 110 and the passive device chip 120 and curing the insulating material. In an implementation, the insulating material may be formed to cover the passive device chip 120. Thus, the rear surface of the passive device chip 120 may not be exposed to the outside. In addition, a portion of the insulating material may be provided to cover the top surface of the connection substrate 110. Thus, the lower core pads 117 of the connection substrate 110 may not be exposed to the outside. Alternatively, the insulating layer 140 may not cover the top surface of the connection substrate 110 or the top surface of the passive device chip 120.

In an implementation, the lower substrate pads 102 may be formed on the insulating layer 140. As shown in FIG. 16, the insulating layer 140 may be patterned to form openings exposing the lower core pads 117. A conductive layer may be formed on the insulating layer 140 to cover the top surface of the insulating layer 140 and fill the openings. The conductive layer may be patterned to form the lower substrate pads 102. The lower substrate pads 102 may be provided to pass through the opening or penetrate the insulating layer 140 and may be coupled to the lower core pads 117. The following description will be given based on the implementation of FIG. 15.

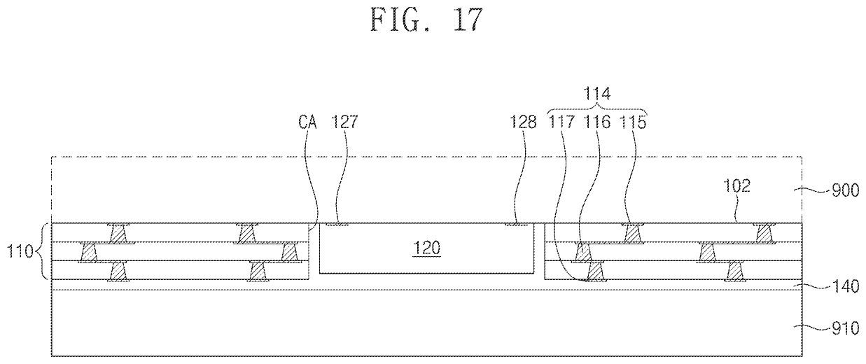

Referring to FIG. 17, a second carrier substrate 910 may be attached to the insulating layer 140. The second carrier substrate 910 may be an insulating substrate containing glass or polymeric materials or a conductive substrate containing a metallic material. The second carrier substrate 910 may be attached to the insulating layer 140 using an adhesive member provided on a top surface thereof. In an implementation, the adhesive member may include an adhesive tape. Thereafter, the first carrier substrate 900 may be removed. As a result of the removal of the first carrier substrate 900, the first and second passive device pads 127 and 128 of the passive device chip 120 and the upper core pads 115 of the connection substrate 110 may be exposed to the outside.

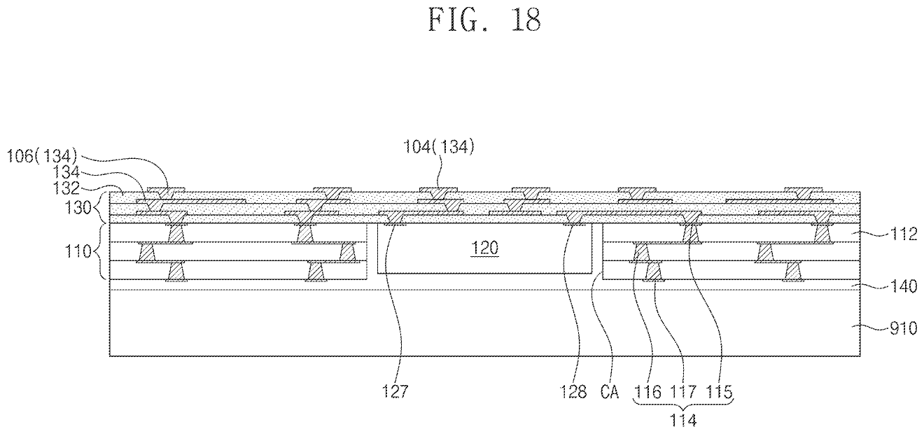

Referring to FIG. 18, the upper interconnection layer 130 may be formed on the top surface of the connection substrate 110 and the top surface of the passive device chip 120, which are exposed by removing the first carrier substrate 900. For example, the upper insulating patterns 132 and the upper interconnection patterns 134, which constitute the upper interconnection layer 130, may be formed on the top surface of the connection substrate 110 and the top surface of the passive device chip 120. Some of the upper insulating patterns 132 may be formed by forming an insulating layer (e.g., a silicon oxide layer) on the top surface of the connection substrate 110 and the top surface of the passive device chip 120 and patterning the insulating layer. The upper insulating patterns 132 may be formed to expose the first and second passive device pads 127 and 128 of the passive device chip 120 and the upper core pads 115 of the connection substrate 110. The upper interconnection patterns 134 may be formed by forming a conductive layer on the top surfaces of the upper insulating patterns 132 and patterning the conductive layer. The upper interconnection patterns 134 may be electrically connected to at least one of the first and second passive device pads 127 and 128 and the upper core pads 115. Others of the upper insulating patterns 132 may be formed by forming an insulating layer on the top surfaces of the upper interconnection patterns 134 and patterning the insulating layer. Here, some of the upper interconnection patterns 134 may be exposed to the outside of the upper insulating patterns 132.

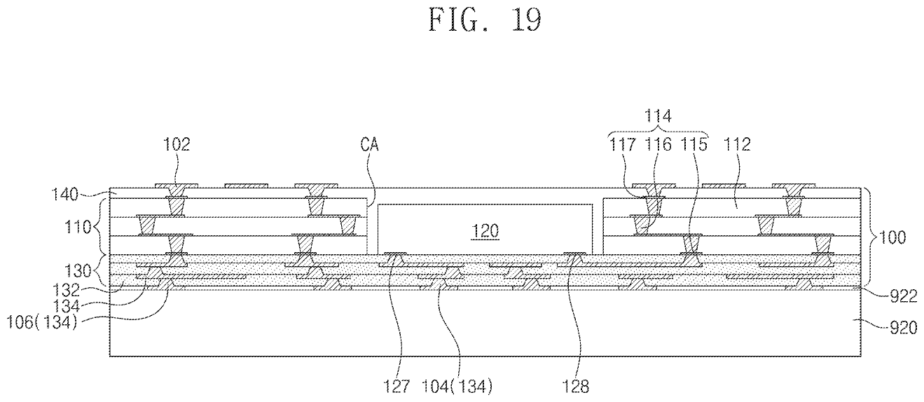

Referring to FIG. 19, a third carrier substrate 920 may be attached to the upper interconnection layer 130. The third carrier substrate 920 may be an insulating substrate containing glass or polymeric materials or a conductive substrate containing a metallic material. The third carrier substrate 920 may be attached to the upper interconnection layer 130 through an adhesive member 922 provided on a top surface thereof. In an implementation, the adhesive member 922 may include an adhesive tape. Thereafter, the second carrier substrate 910 may be removed.

The lower substrate pads 102 may be formed on the top surface of the insulating layer 140, which is exposed by removing the second carrier substrate 910. The insulating layer 140 may be patterned to form openings exposing the lower core pads 117. A conductive layer may be formed on the insulating layer 140 to cover the top surface of the insulating layer 140 and fill the openings. The conductive layer may be patterned to form the lower substrate pads 102. The lower substrate pads 102 may be provided to pass through the opening or penetrate the insulating layer 140 and may be coupled to the lower core pads 117. As a result of the above process, a package substrate may be fabricated.

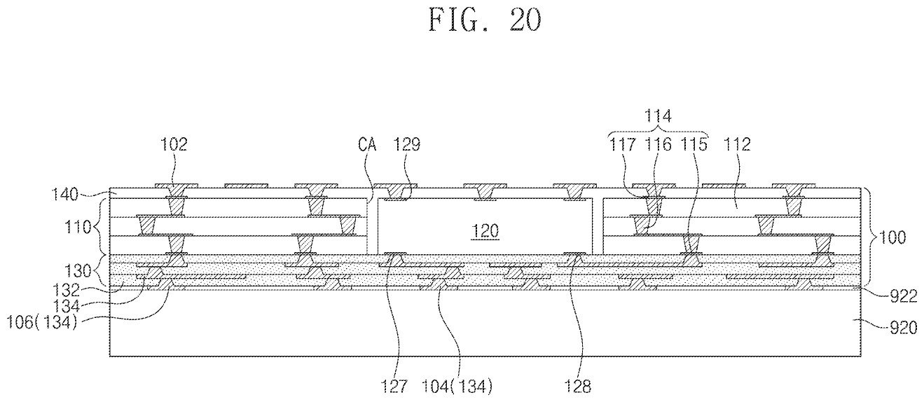

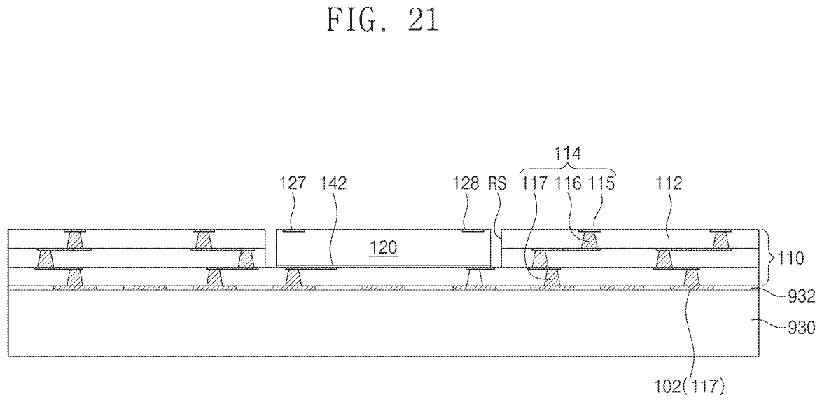

If, as in FIGS. 5 to 7, the passive device chip 120 further includes the third passive device pads 129 provided on a rear surface thereof, the lower substrate pads 102 may be formed on the passive device chips 120. As shown in FIG. 20, the insulating layer 140 may be patterned to form openings exposing the lower core pads 117 and the third passive device pads 129. A conductive layer may be formed on the insulating layer 140 to cover the top surface of the insulating layer 140 and fill the openings. The conductive layer may be patterned to form the lower substrate pads 102. The lower substrate pads 102 may be provided to pass through the opening or penetrate the insulating layer 140 and may be coupled to the lower core pads 117 and the third passive device pads 129. The following description will be given based on the implementation of FIG. 19.

Referring back to FIG. 1, the third carrier substrate 920 and the adhesive member 922 may be removed. As a result of the removal of the third carrier substrate 920, the upper interconnection layer 130 may be exposed to the outside.

The substrate posts 450 may be formed on the top surface of the upper interconnection layer 130, which is exposed by removing the third carrier substrate 920. For example, a sacrificial layer may be formed on the top surface of the package substrate 100. Penetration holes may be formed to penetrate the sacrificial layer and expose the second upper substrate pads 106. The substrate posts 450 may be formed by filling the penetration holes with a conductive material. Thereafter, the sacrificial layer may be removed.

The first and second semiconductor chips 200 and 300 may be sequentially stacked on the package substrate 100. The first and second semiconductor chips 200 and 300 may be mounted on the package substrate 100 in a flip chip manner.

The mold layer 400 may be formed on the package substrate 100. For example, the mold layer 400 may be formed by forming an insulating material on the package substrate 100 to cover the first and second semiconductor chips 200 and 300 and the substrate posts 450 and curing the insulating material.

The outer terminals 150 may be provided on the bottom surface of the package substrate 100. The outer terminals 150 may be formed by providing soldering members (e.g., solder balls or solder bumps) on surfaces of the lower substrate pads 102.

As a result of the above process, the semiconductor package may be fabricated to have the same structure as the semiconductor package 1.

FIGS. 21 to 23 are sectional views illustrating an example of a method of fabricating a semiconductor package.

Referring to FIG. 21, the connection substrate 110 may be provided. The connection substrate 110 may be the same as or similar to the connection substrate 110 described with reference to FIGS. 9 and 10. For example, the connection substrate 110 may include the core insulating pattern 112 and the core conductive pattern 114. The core conductive pattern 114 may include the upper core pads 115, the core interconnection lines 116, and the lower core pads 117. A fourth carrier substrate 930 may be attached to the bottom surface of the connection substrate 110. The fourth carrier substrate 930 may be an insulating substrate containing glass or polymeric materials or a conductive substrate containing a metallic material. The fourth carrier substrate 930 may be attached to the core insulating pattern 112 and the lower core pads 117 of the connection substrate 110 using an adhesive member, which is provided on a top surface of the fourth carrier substrate 930. In an implementation, the adhesive member may include an adhesive tape.

The internal region RS may be formed in the connection substrate 110. The internal region RS may be formed by removing a portion of the connection substrate 110. In an implementation, the internal region RS may be formed by performing an etching process, such as a drilling process, a laser ablation process, or a laser cutting process. The internal region RS may be a vertically-recessed empty space, which is formed in an upper portion of the connection substrate 110. That is, the internal region RS may not fully penetrate the connection substrate 110 in a vertically direction. The removed portion of the connection substrate 110 may be a space, in which the passive device chip 120 will be provided in a subsequent process.

The passive device chip 120 may be provided on the first carrier substrate 900. The passive device chip 120 may be disposed in the internal region RS of the connection substrate 110. In an implementation, the passive device chip 120 may be disposed in the internal region RS and may be attached to the internal region RS using the adhesive layer 142. The adhesive layer 142 may be interposed between the rear surface of the passive device chip 120 and the bottom surface of the internal region RS. Here, the passive device chip 120 may be provided such that the first and second passive device pads 127 and 128 are placed near the top surface of the connection substrate 110. That is, the passive device chip 120 may be attached to the connection substrate 110 in a face-up manner, and the top surface of the passive device chip 120 may be a front surface.

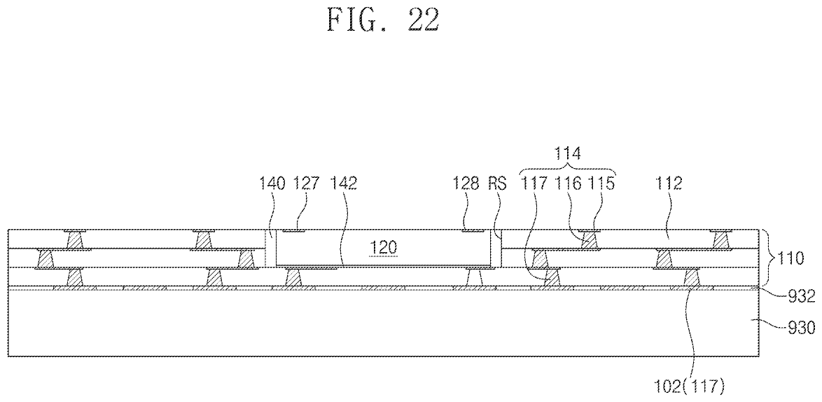

Referring to FIG. 22, the insulating layer 140 may be formed on the fourth carrier substrate 930. The insulating layer 140 may be formed to fill a space between the connection substrate 110 and the passive device chip 120. For example, the insulating layer 140 may be formed by injecting an insulating material into the space between the connection substrate 110 and the passive device chip 120 and curing the insulating material. In an implementation, the insulating material may not cover the top surface of the passive device chip 120 and the top surface of the connection substrate 110. The top surface of the insulating layer 140 may be coplanar with the top surface of the passive device chip 120 and the top surface of the connection substrate 110.

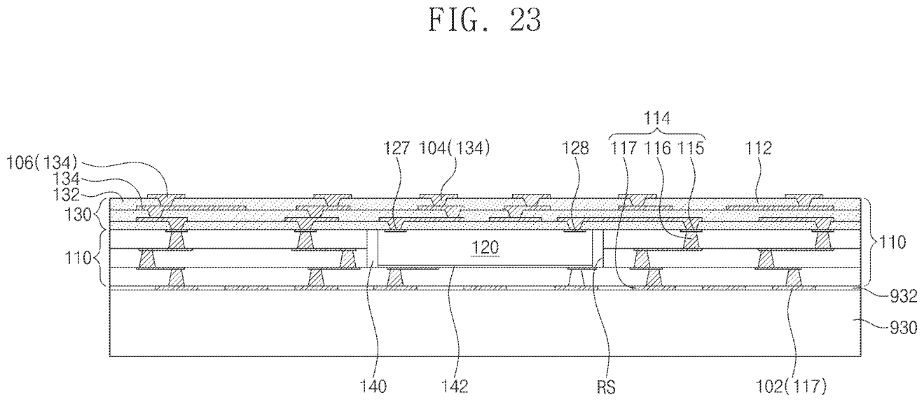

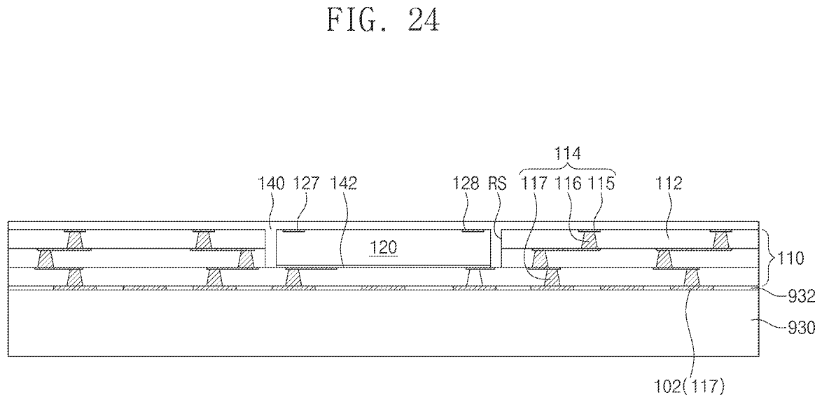

Referring to FIG. 23, the upper interconnection layer 130 may be formed on the connection substrate 110 and the passive device chip 120. For example, the upper insulating patterns 132 and the upper interconnection patterns 134, which constitute the upper interconnection layer 130, may be formed on the top surface of the connection substrate 110 and the top surface of the passive device chip 120. Some of the upper insulating patterns 132 may be formed by forming an insulating layer (e.g., a silicon oxide layer) on the top surface of the connection substrate 110 and the top surface of the passive device chip 120 and patterning the insulating layer. The upper insulating patterns 132 may be formed to expose the first and second passive device pads 127 and 128 of the passive device chip 120 and the upper core pads 115 of the connection substrate 110. The upper interconnection patterns 134 may be formed by forming a conductive layer on the top surfaces of the upper insulating patterns 132 and patterning the conductive layer. The upper interconnection patterns 134 may be electrically connected to at least one of the first and second passive device pads 127 and 128 and the upper core pads 115. Others of the upper insulating patterns 132 may be formed by forming an insulating layer on the top surfaces of the upper interconnection patterns 134 and patterning the insulating layer. Here, some of the upper interconnection patterns 134 may be exposed to the outside of the upper insulating patterns 132.

Referring back to FIG. 9, the substrate posts 450 may be formed on the top surface of the upper interconnection layer 130. For example, a sacrificial layer may be formed on the top surface of the package substrate 100. Penetration holes may be formed to penetrate the sacrificial layer and expose the second upper substrate pads 106. The substrate posts 450 may be formed by filling the penetration holes with a conductive material. Thereafter, the sacrificial layer may be removed.

The first and second semiconductor chips 200 and 300 may be sequentially stacked on the package substrate 100. The first and second semiconductor chips 200 and 300 may be mounted on the package substrate 100 in a flip chip manner.

The mold layer 400 may be formed on the package substrate 100. For example, the mold layer 400 may be formed by forming an insulating material on the package substrate 100 to cover the first and second semiconductor chips 200 and 300 and the substrate posts 450 and curing the insulating material.

The fourth carrier substrate 930 may be removed. As a result of the removal of the fourth carrier substrate 930, the bottom surface of the connection substrate 110 may be exposed to the outside.

The outer terminals 150 may be provided on the bottom surface of the package substrate 100. The outer terminals 150 may be formed by providing soldering members (e.g., solder balls or solder bumps) on surfaces of the lower substrate pads 102.

As a result of the above process, the semiconductor package may be fabricated to have the same structure as the semiconductor package 5.

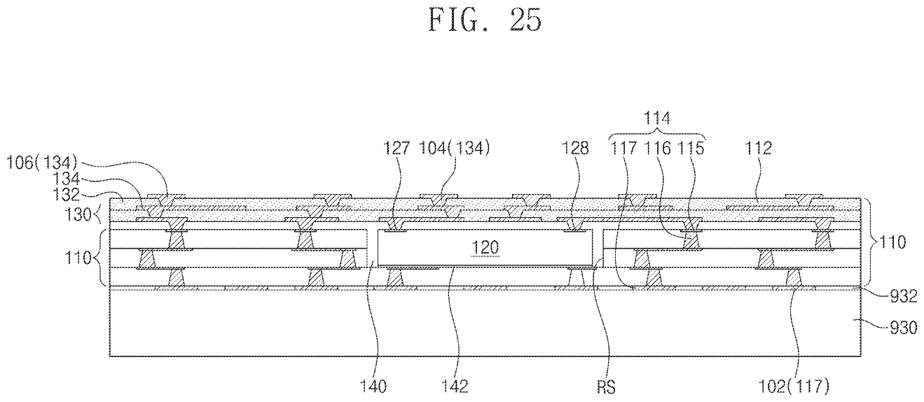

FIGS. 24 and 25 are sectional views illustrating an example of a method of fabricating a semiconductor package.

Referring to FIG. 24, the insulating layer 140 may be formed on the fourth carrier substrate 930 in the resulting structure of FIG. 21. The insulating layer 140 may be provided to fill a space between the connection substrate 110 and the passive device chip 120. For example, the insulating layer 140 may be formed by injecting an insulating material into the space between the connection substrate 110 and the passive device chip 120 and curing the insulating material. In an implementation, the insulating material may be formed to cover the passive device chip 120. Thus, a front surface of the passive device chip 120 may not be exposed to the outside. In addition, a portion of the insulating material may be provided to cover the top surface of the connection substrate 110. Thus, the upper core pads 115 of the connection substrate 110 may not be exposed to the outside.

Referring to FIG. 25, the upper interconnection layer 130 may be formed on the insulating layer 140. For example, the upper insulating patterns 132 and the upper interconnection patterns 134, which constitute the upper interconnection layer 130, may be formed on the top surface of the insulating layer 140.

The insulating layer 140 may be patterned to expose the first and second passive device pads 127 and 128 of the passive device chip 120 and the upper core pads 115 of the connection substrate 110. Some of the upper interconnection patterns 134 may be formed by forming a conductive layer on the top surface of the insulating layer 140 and patterning the conductive layer. The upper interconnection patterns 134 may be electrically connected to at least one of the first and second passive device pads 127 and 128 and the upper core pads 115. An insulating layer (e.g., a silicon oxide layer) may be formed on the insulating layer 140 to cover the upper interconnection patterns 134, and then, the insulating layer may be patterned to form some of the upper insulating patterns 132. The upper interconnection layer 130 may be formed by repeating the process of forming some of the upper interconnection patterns 134 and some of the upper insulating patterns 132. Here, some of the upper interconnection patterns 134 may be exposed to the outside of the upper insulating patterns 132.

Referring back to FIG. 10, the substrate posts 450 may be formed on the top surface of the upper interconnection layer 130. For example, a sacrificial layer may be formed on the top surface of the package substrate 100. Penetration holes may be formed to penetrate the sacrificial layer and expose the second upper substrate pads 106. The substrate posts 450 may be formed by filling the penetration holes with a conductive material. Thereafter, the sacrificial layer may be removed.

The first and second semiconductor chips 200 and 300 may be sequentially stacked on the package substrate 100. The first and second semiconductor chips 200 and 300 may be mounted on the package substrate 100 in a flip chip manner.

The mold layer 400 may be formed on the package substrate 100. For example, the mold layer 400 may be formed by forming an insulating material on the package substrate 100 to cover the first and second semiconductor chips 200 and 300 and the substrate posts 450 and curing the insulating material.

The fourth carrier substrate 930 may be removed. As a result of the removal of the fourth carrier substrate 930, the bottom surface of the connection substrate 110 may be exposed to the outside.

The outer terminals 150 may be provided on the bottom surface of the package substrate 100. The outer terminals 150 may be formed by providing soldering members (e.g., solder balls or solder bumps) on surfaces of the lower substrate pads 102.

As a result of the above process, the semiconductor package may be fabricated to have the same structure as the semiconductor package 6.

In an example semiconductor package, an additional space for mounting a passive device chip on or below a package substrate may not be required, and thus, it may be possible to reduce a size of the semiconductor package. In addition, substrate pads may be more freely disposed on a bottom surface of the package substrate. Furthermore, semiconductor chips may be electrically connected to the passive device chip through only an upper interconnection layer of the package substrate, and thus, it may be possible to reduce a length of electric connection paths between the semiconductor chips and the passive device chip, thereby realizing a semiconductor package with improved electrical characteristics.

The passive device chip may be directly connected to the substrate pads, and in this case, a length of electric connection paths between the passive device chip and the substrate pads may be reduced. As a result, electrical characteristics of the semiconductor package may be improved.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While example implementations of the concepts described herein have been particularly shown and described, it will be understood by one of ordinary skill in the art that variations in form and detail may be made therein without departing from the spirit and scope of the attached claims.

What is claimed is:

1. A semiconductor package, comprising:
a substrate having a first side and a second side opposite to the first side;
a first semiconductor chip mounted at the first side of the substrate;
a mold layer at the first side of the substrate, the mold layer covering the first semiconductor chip; and
outer terminals at the second side of the substrate,
wherein the substrate comprises:
a first interconnection layer;
a second interconnection layer;
a passive device mounted at a bottom surface of the second interconnection layer; and
a connection member at a side of the passive device and between the first interconnection layer and the second interconnection layer, the connection member connecting the first interconnection layer to the second interconnection layer,
wherein the outer terminals are coupled to a bottom surface of the first interconnection layer,
wherein the passive device comprises a first pad at a top surface of the passive device, and
wherein an interconnection pattern of the second interconnection layer contacts the first pad.

2. The semiconductor package of claim 1, wherein the substrate comprises:
a connection substrate between the first interconnection layer and the second interconnection layer, wherein the passive device is located at an opening of the connection substrate; and
an insulating layer provided at the opening and filling a space between the connection substrate and the passive device, and
wherein the connection member comprises a substrate interconnection pattern at the connection substrate.

3. The semiconductor package of claim 2, wherein the opening penetrates the connection substrate vertically,
wherein the passive device contacts the second interconnection layer, and
wherein an interconnection pattern of the first interconnection layer is disconnected from the passive device.

4. The semiconductor package of claim 3, wherein the outer terminals are disposed outside the passive device in a plan view of the substrate.

5. The semiconductor package of claim 2, wherein the opening is at an upper portion of the connection substrate and has a recess shape,
wherein a lower portion of the connection substrate covers a bottom surface of the passive device, and
wherein the lower portion of the connection substrate corresponds to the second interconnection layer.

6. The semiconductor package of claim 5, wherein an adhesive layer is between the passive device and a bottom surface of the opening.

7. The semiconductor package of claim 1, wherein the substrate comprises an insulating layer filling a space between the first interconnection layer and the second interconnection layer, and
wherein the connection member comprises a substrate post vertically penetrating the insulating layer.

8. The semiconductor package of claim 7, wherein the insulating layer is at a bottom surface of the second interconnection layer and covers the passive device.

9. The semiconductor package of claim 1, wherein the passive device comprises:
a penetration via vertically penetrating the passive device; and
a second pad positioned at a bottom surface of the passive device and connected to the penetration via, wherein an interconnection pattern of the first interconnection layer contacts the second pad and the connection member.

10. The semiconductor package of claim 9, wherein at least one outer terminal of the outer terminals is positioned below the passive device.

11. The semiconductor package of claim 1, comprising:
a second semiconductor chip stacked on the first semiconductor chip and electrically connected to the substrate through a chip via that vertically penetrates the first semiconductor chip; and
a conductive post vertically penetrating the mold layer and coupled to the substrate.

12. The semiconductor package of claim 1, wherein the passive device comprises a capacitor, a resistor, or an inductor.

13. A semiconductor package, comprising:
a substrate having a first side and a second side opposite to the first side;
a first semiconductor chip and a second semiconductor chip stacked at the first side of the substrate, the second semiconductor chip electrically connected to the substrate through a chip via that vertically penetrates the first semiconductor chip;
a mold layer at the first side of the substrate, the mold layer covering the first semiconductor chip and the second semiconductor chip; and
outer terminals at the second side of the substrate,
wherein the substrate comprises:
an interconnection layer;
a passive device disposed at a bottom surface of the interconnection layer;
an insulating layer at the bottom surface of the interconnection layer, the insulating layer enclosing the passive device;
substrate pads positioned at a bottom surface of the passive device; and
a connection member at a side of the passive device and connecting the interconnection layer to the substrate pads, and
wherein an active surface of the passive device contacts the bottom surface of the interconnection layer.

14. The semiconductor package of claim 13, wherein the connection member comprises substrate posts at the side of the passive device and vertically penetrates the insulating layer, and
wherein the substrate posts connect an interconnection pattern of the interconnection layer to the substrate pads.

15. The semiconductor package of claim 13, wherein the substrate comprises a connection substrate at the bottom surface of the interconnection layer, an opening of the connection substrate vertically penetrating the connection substrate, and the passive device is located in the opening,
wherein the connection member comprises a substrate interconnection pattern in the connection substrate,
wherein the substrate interconnection pattern connects an interconnection pattern of the interconnection layer to the substrate pads, and
wherein the insulating layer is at the opening and fills a space between the connection substrate and the passive device.

16. The semiconductor package of claim 15, wherein the insulating layer covers a bottom surface of the connection substrate, and
wherein the substrate pads penetrates the insulating layer and are coupled to the connection members.

17. The semiconductor package of claim 13, wherein the substrate comprises a connection substrate, at the bottom surface of the interconnection layer, a recess of the connection substrate opens toward the interconnection layer, and the passive device is in the recess,
wherein the connection member comprises a substrate interconnection pattern in the connection substrate,
wherein the substrate pads comprise a portion of the substrate interconnection pattern exposed near a bottom surface of the connection substrate, and
wherein the insulating layer in the recess fills a space between the connection substrate and the passive device.

18. The semiconductor package of claim 13, wherein the passive device comprises:
passive device electrodes;
a dielectric layer disposed between two passive device electrodes of the passive device electrodes; and
passive device pads at the active surface of the passive device and connected to the passive device electrodes, respectively,
wherein the passive device pads are directly connected to an interconnection pattern of the interconnection layer.

19. The semiconductor package of claim 13, wherein the passive device comprises:
a first electrode and a second electrode;
a dielectric layer disposed between the first electrode and the second electrode;
a first passive device pad at the active surface of the passive device and connected to the first electrode;
a second passive device pad at an inactive surface of the passive device and connected to the second electrode; and
a penetration via vertically penetrating the passive device and connecting the first passive device pad to the second passive device pad,
wherein the first passive device pad is directly connected to an interconnection pattern of the interconnection layer, and
the second passive device pad is directly connected to at least one substrate pad of the substrate pads.

20. A semiconductor package, comprising:
a core layer;
an upper interconnection layer at a top surface of the core layer, the upper interconnection layer comprising an insulating pattern and an interconnection pattern;
a passive device in an internal region formed in the core layer and electrically connected to the upper interconnection layer;
a first semiconductor chip mounted at the upper interconnection layer, the first semiconductor chip comprising a chip via vertically penetrating the first semiconductor chip;
a second semiconductor chip stacked on the first semiconductor chip and electrically connected to the upper interconnection layer through the chip via;
a mold layer on the upper interconnection layer enclosing the first semiconductor chip and the second semiconductor chip;
a conductive post on the upper interconnection layer vertically penetrating the mold layer at a side of the first semiconductor chip;
outer pads positioned below the core layer and the passive device, the outer pads electrically connected to the core layer; and
outer terminals on the outer pads,
wherein the passive device comprises:
a first electrode and a second electrode spaced apart from the first electrode;
a dielectric material filling a space between the first electrode and the second electrode; and
a first sub-electrode and a second sub-electrode alternately between the first electrode and the second electrode,
wherein the first sub-electrode is connected to the first electrode, and
wherein the second sub-electrode is connected to the second electrode.
